(19) United States
(12) Patent Application Publication
(10) Pub. No.: US 2012/0145443 A1
(43) Pub. Date: Jun. 14, 2012

(54) CIRCUIT BOARD WITH DOUBLE-SIDED UNIVERSAL CIRCUIT LAYOUT AND LAYOUT METHOD THEREOF

(75) Inventors: KUO-CHAN PENG, Pingzhen City (TW); CHING-FENG HSIEH, Taipei City (TW)

(73) Assignee: ASKEY COMPUTER CORP., TAIPEI (TW)

(21) Appl. No.: 13/009,974

(22) Filed: Jan. 20, 2011

(30) Foreign Application Priority Data
Dec. 14, 2010 (TW) 099143753

(51) Int. Cl. H05K 1/11; G06F 17/50

(52) U.S. Cl. 174/260; 716/137

(57) ABSTRACT

A circuit board with double-sided universal circuit layout for laying out electronic components has a first side with a first circuit layout thereon and an opposing second side with a second circuit layout thereon; hence, the first circuit layout and the second circuit layout are disposed on the opposing sides of the circuit board, respectively. The first circuit layout and the second circuit layout feature electronic circuits having the same function, thereby allowing users to selectively install the electronic components at one of the first circuit layout and the second circuit layout as needed and still have access to the electronic circuits having the same function. A layout method for use with the circuit board with double-sided universal circuit layout is further introduced.

### CROSS-REFERENCE TO RELATED APPLICATION

This non-provisional application claims priority under 35 U.S.C. §119(a) on Patent Application No(s). 099143753 filed in Taiwan, R.O.C. on Dec. 14, 2010, the entire contents of which are hereby incorporated by reference.

### FIELD OF THE TECHNOLOGY

The present invention relates to circuit boards with double-sided universal circuit layout and layout methods thereof, and more particularly, to a circuit board for disposing electronic components on two sides of the circuit board as needed and a layout method thereof.

### BACKGROUND

Due to rapid development of broadband networks and digital information, a lot of information-based communication network apparatuses are widely distributed around the world for use with communication products, such as access points (AP) of wireless networks, personal digital assistants (PDA), notebook computers, and portable mobile devices, so as for communication services to be provided by means of the apparatuses in a convenient, efficient, and diverse manner.

The information-based communication network apparatuses operate either outdoors or indoors. Compared to their indoor counterparts, the outdoor information-based communication network apparatuses have higher waterproof and dust-free standards to meet the need for coping with unstable outdoor conditions (such as wind, sunshine, or rainfall). In general, the outdoor information-based communication network apparatuses meet the standards by means of a hermetically sealed casing.

Although the prior art meets the waterproof and dust-free needs, the prior art still has to address issues regarding dissipation of heat generated by electronic components dispose inside the casing. To this end, the prior art offers a solution whereby a circuit board having electronic components thereon is in direct contact with a casing in order to facilitate heat dissipation. In 6 rf information-based communication network apparatus should be installed on the back side of a circuit board of the outdoor information-based communication network apparatus. In practice, due to spatial limitation of the casing, it is impossible for large-capacity and large-sized electronic components to be installed on the back side of the circuit board; hence, the electronic components are installed on the front side of the circuit board.

Unlike their outdoor counterparts, the indoor information-based communication network apparatuses have their electronic components installed on the front side of a circuit board. Hence, from a manufacturer's perspective, it is necessary to provide two types of circuit boards for use with the outdoor and indoor information-based communication network apparatuses, respectively, thereby incurring manufacturing costs and weighing down inventory.

Referring to FIG. 1, there is shown a schematic view of a conventional printed circuit board of a network apparatus. As shown in the drawing, an integrated circuit (IC) 1 and electronic components, such as a resistor 4, a capacitor 6, and an inductor 8, are essentially disposed on one side of a circuit board 2. The electronic components differ from each other in dimensions and height. For example, the capacitor 6 is of a larger height than the other ones of the electronic components. When it comes to an outdoor network apparatus, the electronic component-disposed side of the circuit board 2 has to be in direct contact with the casing of the outdoor network apparatus so as to enhance dissipation of heat from the circuit board 2. However, due to the height limitation of the receiving space defined by the casing and the circuit board 2 of the network apparatuses, the resistor 4 and the capacitor 6 which are of a relatively large height are unfit to be received in the receiving space. In general, the maximum allowable height of the electronic components is 6 mm. Hence, only the integrated circuit (IC) 1 and the inductor 8 which are of a relatively small height can be disposed on a casing-contacting side of the circuit board 2. By contrast, the resistor 4 and the capacitor 6 which are of a relatively large height cannot be disposed on the casing-contacting side of the circuit board 2. As a result, the resistor 4 and the capacitor 6 have to be disposed on a non-casing-contacting side of the circuit board 2.

As described above, there is a distinct difference in the design of a circuit board between an indoor network apparatus and an outdoor network apparatus according to the prior art, and, as a result, it is impossible for the indoor network apparatus and the outdoor network apparatus to have a circuit board in common with each other according to the prior art. Hence, the design of different circuit boards for use with the indoor network apparatuses and the outdoor network apparatuses, respectively, according to the prior art incurs manufacturing costs and weighs down inventory. Accordingly, it is imperative to provide a circuit board with double-sided universal circuit layout and a layout method thereof for use with indoor network apparatuses and outdoor network apparatuses equally such that the indoor network apparatuses and the outdoor network apparatuses can operate by means of the functionally alike electrical circuit thereof in an unchanged manner.

### SUMMARY

It is an objective of the present invention to provide a circuit board with double-sided universal circuit layout such that two functionally equivalent electrical circuits can be laid out on two sides of the circuit board, respectively, to thereby allow electronic components to be disposed on one of the two sides of the circuit board.

Another objective of the present invention is to provide a layout method for use with a circuit board with double-sided universal circuit layout such that two functionally equivalent electrical circuits can be laid out on two sides of the circuit board, respectively, to thereby allow electronic components to be disposed on one of the two sides of the circuit board.

In order to achieve the above and other objectives, the present invention provides a circuit board with double-sided universal circuit layout for laying out electronic components thereon. The circuit board has a first side and an opposing second side, and comprises a first circuit layout and a second circuit layout. The first circuit layout is disposed on the first side of the circuit board. The second circuit layout corresponds in position to the first circuit layout and is disposed on the second side of the circuit board. Functionally equivalent electrical circuits are laid out at the first circuit layout and the second circuit layout, respectively, such that the electronic components are selectively disposed at one of the first circuit layout and the second circuit layout.

In order to achieve the above and other objectives, the present invention provides a layout method for use with a circuit board with double-sided universal circuit layout. The circuit board has a first side and an opposing second side, such that external electronic components are disposed on the circuit board. The method comprises the steps of: providing a first circuit layout on the first side of the circuit board; and laying out a second circuit layout corresponding in position to the first circuit layout on the second side of the circuit board, wherein the second circuit layout and the first circuit layout have functionally equivalent electrical circuits whereby the electronic components are selectively disposed at one of the first circuit layout and the second circuit layout.

Compared with the prior art, the present invention provides a circuit board with double-sided universal circuit layout and a layout method thereof such that functions and operation of electronic components selectively laid out on one of the two sides of the circuit board remain unchanged, using functionally equivalent electrical circuits. Hence, a circuit board and a layout method thereof of the present invention are applicable to conventional circuit board design of indoor network apparatuses and outdoor network apparatuses.

### BRIEF DESCRIPTION OF THE DRAWINGS

To enable persons skilled in the art to fully understand the objectives, features, and advantages of the present invention, the present invention is hereunder illustrated with specific embodiments in conjunction with the accompanying drawings, in which:

FIG. 1 (PRIOR ART) is a schematic view of a conventional printed circuit board of a network apparatus;

FIG. 2A and FIG. 2B are schematic views of circuit layout of a first side and a second side of a circuit board with double-sided universal circuit layout according to an embodiment of the present invention, respectively; and

FIG. 3 is a flow chart of a layout method for use with a circuit board with double-sided universal circuit layout according to an embodiment of the present invention.

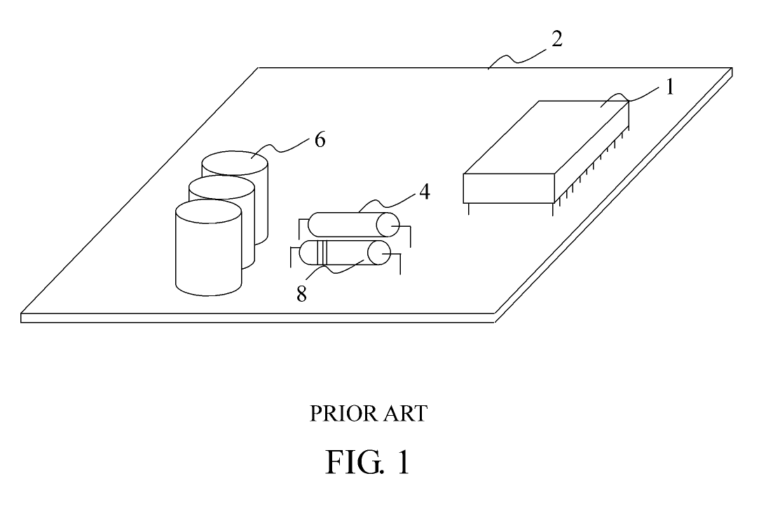

### DETAILED DESCRIPTION

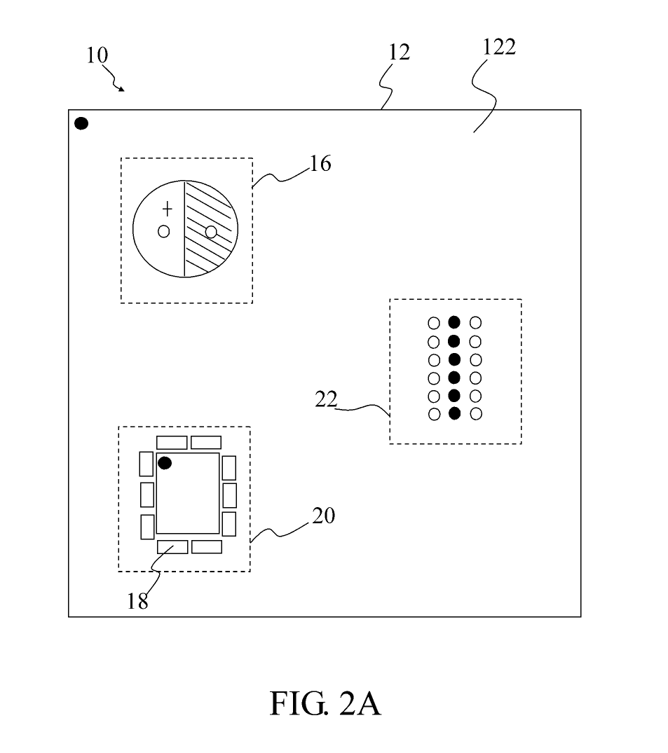

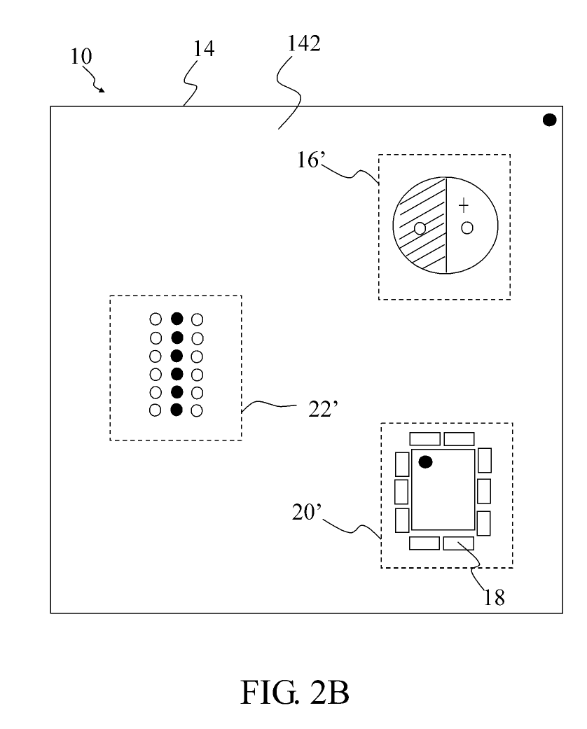

Referring to FIG. 2A and FIG. 2B, there are shown schematic views of circuit layout of a first side and a second side of a circuit board with double-sided universal circuit layout according to an embodiment of the present invention, respectively. A circuit board 10 with double-sided universal circuit layout is configured to carry electronic components thereon. The circuit board 10 has a first side 12 and an opposing second side 14.

Referring to FIG. 2A, the first side 12 of the circuit board 10 has a first circuit layout 122. For example, the first circuit layout 122 comprises a plurality of electrical contacts corresponding in position to electronic components and electrical circuit connections between the electrical contacts. In an embodiment, although a portion of the first circuit layout 122 is dedicated to circuit layout of the first side 12, another portion of the first circuit layout 122 provides circuit layout for both the first side 12 and the opposing second side 14 as described in detail below.

Referring to FIG. 2B, the second side 14 of the circuit board 10 has a second circuit layout 142 corresponding in position to the first circuit layout 122. The second circuit layout 142 comprises a plurality of electrical contacts corresponding in position to the electronic components that can be effectuated by the first circuit layout 122 and electrical circuit connections between the electrical contacts. Functionally equivalent electrical circuits are laid out at the first circuit layout 122 and the second circuit layout 142, respectively, such that the electronic components are selectively disposed at one of the first circuit layout 122 and the second circuit layout 142. In addition, the electrical circuit enables electrical connection between the electronic components via an electrical conductive material (such as a wire), such that a specific electronic function can be effectuated by means of the concurrent, interactive and electronic characteristic-based operation of the electronic components. For example, an operational amplifier (OPA), a resistor, and a capacitor together form an integrating circuit or a differentiating circuit when electrically connected by the electrical circuit.

Hence, the first circuit layout 122 and the second circuit layout 142 have functionally equivalent electrical circuits in common with each other, such that electronic components always manifest the same function, whether the electronic components are disposed at the first circuit layout 122 or the second circuit layout 142.

A circuit board with double-sided universal circuit layout is effectuated by circuit layout illustrated in embodiments described hereunder. Electronic components are selectively disposed at the first circuit layout 122 or the second circuit layout 142, according to the characteristics (dimensions and height) of the electronic components.

As regards electronic components of polarity, such as diodes, light-emitting diodes, or polarized capacitors, the electrical circuits of the first circuit layout 122 and the second circuit layout 142 are mirrored to each other, such that the electronic components of polarity are disposed at one of the first circuit layout 122 and the second circuit layout 142. For example, a circuit layout 16 which has positive and negative polarity is laid out at the first circuit layout 122 as shown in FIG. 2A, and a circuit layout 16′ that mirrors the circuit layout 16 at the first circuit layout 122 is laid out at the second circuit layout 142 as shown in FIG. 2B. Hence, the circuit layouts 16, 16′ disposed at the first circuit layout 122 and the second circuit layout 142, respectively, are mirrored to each other, that is, the circuit layouts 16, 16′ appears identical but in reverse.

As regards surface-mounted electronic components, such as integrated circuits or central processing units (CPU), a plurality of pads 18 are disposed at both the first circuit layout 122 and the second circuit layout 142, such that the surface-mounted electronic components are mounted on one of the first circuit layout 122 and the second circuit layout 142 via the pads as needed. For example, a circuit layout 20 comprising the pads 18 is disposed at the first circuit layout 122 as shown in FIG. 2A, and a circuit layout 20′ corresponding in position to the circuit layout 20 is disposed at the second circuit layout 142 as shown in FIG. 2B. The surface-mounted electronic components are disposed at the circuit layout 20 of the first circuit layout 122 or at the circuit layout 20′ of the second circuit layout 142.

As regards dual in-line package (DIP) electronic components, such as a 74XX or 54XX series logic IC or an 80 series single-chip processor, a plurality of parallel rows of socket ends are disposed at the first circuit layout 122 and the second circuit layout 142, such that DIP electronic components are disposed at the first circuit layout 122 and the second circuit layout 142 via the socket ends. For example, the first circuit layout 122 comprises a circuit layout 22 having a plurality of parallel rows of socket ends as shown in FIG. 2A, and the second circuit layout 142 comprises a circuit layout 22′ corresponding in position to the circuit layout 22 as shown in FIG. 2B.

The circuit layouts 22, 22′ have socket ends in common with each other whereby DIP electronic components can be plugged into the first circuit layout 122 and the second circuit layout 142, respectively. In an embodiment, each of the circuit layouts 22, 22′ has three said parallel rows of socket ends, and the intermediate one of three said parallel rows of socket ends serve as the common socket ends. Disposing the DIP electronic components at the first circuit layout 122 entails disposing one row of the DIP electronic components at the common socket ends and the other row of the DIP electronic components at one of three said parallel rows of socket ends. Disposing the DIP electronic components at the second circuit layout 142 entails disposing one row of the DIP electronic components at the common socket ends and the other row of the DIP electronic components at the other one of three said parallel rows of socket ends. Accordingly, no position-corresponding ones of three said parallel rows of socket ends of the circuit layouts 22, 22′ are simultaneously occupied by the DIP electronic components, except the common socket ends.

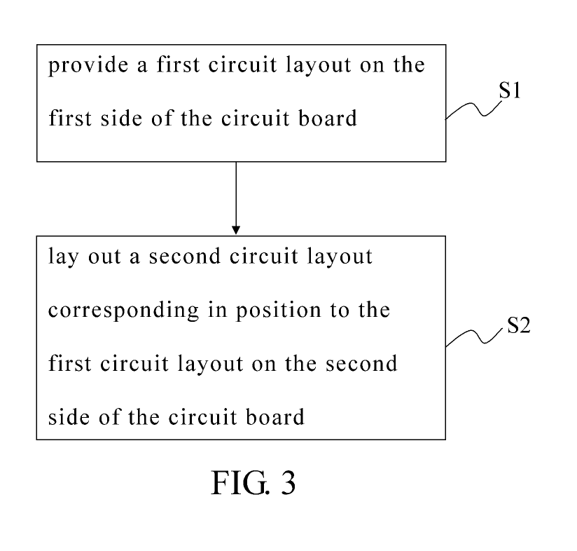

Referring to FIG. 3, there is shown a flow chart of a layout method for use with a circuit board with double-sided universal circuit layout according to an embodiment of the present invention. The method is dedicated to a circuit board that has a first side and an opposing second side for external electronic components to be disposed thereon. The layout method comprises the steps of: providing a first circuit layout on the first side of the circuit board (step S1); and laying out a second circuit layout corresponding in position to the first circuit layout on the second side of the circuit board (step S2). The second circuit layout and the first circuit layout have functionally equivalent electrical circuits whereby the electronic components are selectively disposed at one of the first circuit layout and the second circuit layout.

Several categories of circuit layout methods further provided according to the types of the electronic components are described below.

Electronic components of polarity are laid out at one of the first circuit layout and the second circuit layout and mirrored to each other.

Surface-mounted electronic components are laid out at one of the first circuit layout and the second circuit layout via a plurality of pads disposed therein.

DIP electronic components are plugged into the first circuit layout and the second circuit layout via a plurality of rows of socket ends having at least a common socket end.

The first circuit layout and the second circuit layout are formed by screen printing.

Compared with the prior art, the present invention provides a circuit board with double-sided universal circuit layout and a layout method thereof such that functions and operation of electronic components selectively laid out on one of the two sides of the circuit board remain unchanged, using functionally equivalent electrical circuits. Hence, a circuit board and a layout method thereof of the present invention are applicable to conventional circuit board design of indoor network apparatuses and outdoor network apparatuses. Furthermore, a circuit board and a layout method thereof of the present invention have an advantage: in an outdoor network apparatus scenario, installation of electronic components is not subjected to a spatial limitation, such that electronic components of relatively large height or size can be selectively installed on a spacious side of the circuit board, and thus it is not necessary to install all the electronic components on the same side of the circuit board.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and replacements made to the foregoing embodiments without departing from the spirit embodied in the disclosure of the present invention should fall within the scope of the present invention as set forth in the appended claims. Accordingly, the legal protection for the present invention should be defined by the appended claims.

1. A circuit board with double-sided universal circuit layout, for laying out electronic components thereon, the circuit board having a first side and an opposing second side, comprising:
a first circuit layout disposed on the first side of the circuit board; and
a second circuit layout corresponding in position to the first circuit layout and disposed on the second side of the circuit board, wherein functionally equivalent electrical circuits are laid out at the first circuit layout and the second circuit layout, respectively, such that the electronic components are selectively disposed at one of the first circuit layout and the second circuit layout.

2. The circuit board of claim 1, wherein the electrical circuits of the first circuit layout and the second circuit layout are mirrored to each other, such that the electronic components of polarity are disposed at one of the first circuit layout and the second circuit layout.

3. The circuit board of claim 1, wherein surface-mounted electronic components are mounted on one of the first circuit layout and the second circuit layout via a plurality of pads disposed at the first circuit layout and the second circuit layout.

4. The circuit board of claim 1, wherein a plurality of parallel rows of socket ends are disposed at the first circuit layout and the second circuit layout and comprise at least a common socket end, such that dual in-line package (DIP) electronic components are disposed at the first circuit layout and the second circuit layout.

5. The circuit board of claim 1, wherein the electrical circuits of the first circuit layout and the second circuit layout are formed by screen printing.

6. A layout method for use with a circuit board with double-sided universal circuit layout, the circuit board having a first side and an opposing second side, for laying out external electronic components thereon, the method comprising the steps of:
providing a first circuit layout on the first side of the circuit board; and
laying out a second circuit layout corresponding in position to the first circuit layout on the second side of the circuit board, wherein the second circuit layout and the first circuit layout have functionally equivalent electrical circuits whereby the electronic components are selectively disposed at one of the first circuit layout and the second circuit layout.

7. The method of claim 6, further comprising the step of laying out the first circuit layout and the second circuit layout in a manner that the first circuit layout and the second circuit layout are mirrored to each other, such that the electronic components of polarity are disposed at one of the first circuit layout and the second circuit layout.

8. The method of claim 6, further comprising the step of laying out a plurality of pads on the first circuit layout and the second circuit layout so as for surface-mounted electronic components to be disposed at one of the first circuit layout and the second circuit layout.

9. The method of claim 6, further comprising the step of laying out a plurality of rows of socket ends at the first circuit layout and the second circuit layout, the socket ends having at least a common socket end, such that dual in-line package (DIP) electronic components are disposed at the first circuit layout and the second circuit layout.

10. The method of claim 6, wherein the first circuit layout and the second circuit layout are formed by screen printing.
